(19) United States
(12) Patent Application Publication
(10) Pub. No.: US 2026/0372125 A1
(43) Pub. Date: Nov. 19, 2026

(54) ELECTRONIC PACKAGE AND CIRCUIT STRUCTURE THEREOF

(71) Applicant: SILICONWARE PRECISION INDUSTRIES CO., LTD., Taichung City (TW)

(72) Inventors: Hsiu-Jung LI, Taichung City (TW); Yi-Wen LIU, Taichung City (TW); Wan-Rou CHEN, Taichung City (TW); Hsin-Yin CHANG, Taichung City (TW); Chih-Chieh SUN, Taichung City (TW)

(73) Assignee: SILICONWARE PRECISION INDUSTRIES CO., LTD., Taichung City (TW)

(21) Appl. No.: 19/281,476

(22) Filed: Jul. 25, 2025

(30) Foreign Application Priority Data
May 19, 2025 (TW) 114118708

(51) Int. Cl. H10W 70/60; H10W 70/65; H10W 74/10; H10W 74/15; H10W 90/00

(52) U.S. Cl. CPC H10W 70/611; H10W 70/614; H10W 70/65; H10W 74/117; H10W 90/00; H10W 90/401; H10W 90/701; H10W 70/60; H10W 74/15; H10W 90/724; H10W 90/734

(57) ABSTRACT

An electronic package and a circuit structure thereof are provided. Each of conductive blind vias of the circuit structure is connected to multiple electrical contact pads, and metal sheets adjacent to the conductive blind vias are spaced apart from each other and are not in contact with one another, so that each metal sheet is not daisy-chained to multiple conductive blind vias. Therefore, the conductive blind via as a power circuit or a ground circuit is not connected to the other conductive blind vias, thereby effectively increasing the number of available functional contacts.

### BACKGROUND

### 1. Technical Field

The present disclosure relates to a semiconductor structure, and more particularly, to an electronic package and a circuit structure thereof.

### 2. Description of Related Art

In recent years, the rapid growth of portable electronic products has driven related developments toward higher density, higher performance, and the trend of lighter, thinner, shorter, and smaller form factors. Accordingly, high performance computing (HPC) technologies have become increasingly important and widely applied in modern life, such as in medical technology for cancer drug development or in autonomous vehicle sensing and computation.

To meet requirements for compactness and high density, the industry has developed various multifunctional package types featuring multiple chips, high circuit layer counts, large fan-out dimensions, and advanced thermal designs. Examples include fan-out multi-chip module (FOMCM) structures and fan-out embedded bridge (FOEB) die structures.

FIG. 1A and FIG. 1B are schematic views of a circuit structure 1 of a conventional semiconductor package. As shown in FIG. 1A and FIG. 1B, the circuit structure 1 includes an insulating body 10, a circuit layer 11 bonded to the insulating body 10, a plurality of conductive blind vias 12 formed in the insulating body 10, and a copper sheet 13 bonded to the insulating body 10. The insulating body 10 includes an insulating layer 100. The circuit layer 11 has a plurality of electrical contact pads 110. The conductive blind vias 12 are electrically connected to the circuit layer 11. Each conductive blind via 12 is connected to a single electrical contact pad 110. At least one conductive blind via 12 is served as a power blind via 12a or a ground blind via 12b. The single copper sheet 13 is connected to the power blind via 12a (or the ground blind via 12b) and multiple conductive blind vias 12.

Moreover, an insulating protective layer 14 may be formed on the insulating body 10 to cover the circuit layer 11, and the insulating protective layer 14 is formed with an opening 140 exposing the plurality of electrical contact pads 110 for bonding to a plurality of conductive bumps 15.

However, in the conventional circuit structure 1, the large copper sheet 13 is used to daisy-chain the power blind via 12a (or the ground blind via 12b) and multiple conductive blind vias 12, resulting in a single power blind via 12a (or ground blind via 12b) being daisy-chained to other electrical contact pads 110, thereby greatly reducing the number of available functional contacts (inputs/outputs).

Furthermore, the large-area copper sheet 13 of the conventional circuit structure 1 hampers stress dispersion and leads to stress concentration. As shown in FIG. 1C, the resulting warpage in the circuit structure 1 makes mounted semiconductor chip (not shown) susceptible to cracking during subsequent processes.

Therefore, how to overcome the above-mentioned problems of the prior art has become a challenge that the industry needs to overcome urgently.

### SUMMARY

In view of the above-mentioned deficiencies of the prior art, the present disclosure provides a circuit structure, which comprises: an insulating body including an insulating layer; a circuit layer formed on the insulating body and having a plurality of electrical contact pads; a plurality of conductive blind vias formed in the insulating body and electrically connected to the circuit layer, each of the plurality of conductive blind vias being connected to the plurality of electrical contact pads; and a plurality of metal sheets disposed on the insulating body and adjacent to the plurality of conductive blind vias, the plurality of metal sheets being spaced apart from each other and not in contact with one another.

In the aforementioned circuit structure, the circuit layer is formed in accordance with a redistribution layer specification.

In the aforementioned circuit structure, at least one of the plurality of conductive blind vias is used as a power circuit.

In the aforementioned circuit structure, at least one of the plurality of conductive blind vias is used as a ground circuit.

The present disclosure also provides an electronic package, which comprises: the aforementioned circuit structure; and an electronic element bonded to the plurality of electrical contact pads via a plurality of conductive bumps and electrically connected to the circuit layer.

In the aforementioned electronic package, the electronic element is disposed on one side of the circuit structure, and a plurality of conductive elements are disposed on the other side of the circuit structure.

The present disclosure further provides an electronic package, which comprises: a carrying structure including a routing layer; a plurality of conductive pillars disposed on one side of the carrying structure and electrically connected to the routing layer; an encapsulation layer encapsulating the plurality of conductive pillars; the aforementioned circuit structure disposed on the encapsulation layer and electrically connected to the plurality of conductive pillars; and an electronic element bonded to the plurality of electrical contact pads via a plurality of conductive bumps and electrically connected to the circuit layer.

In the aforementioned electronic package, the encapsulation layer is embedded with an intermediate element having a plurality of conductive through-silicon vias and electrically connected to the routing layer and the circuit layer.

In the aforementioned electronic package, the encapsulation layer is embedded with an electrical bridge element electrically connected to the routing layer and the circuit layer.

In the aforementioned electronic package, the present disclosure further comprises: a plurality of conductive elements disposed on the other side of the carrying structure.

As can be seen from the above, in the electronic package and the circuit structure thereof of the present disclosure, the metal sheets of the circuit structure are spaced apart from each other and are not in contact with one another, so that a copper-break structure is formed, and each metal sheet is not daisy-chained to multiple conductive blind vias. Therefore, compared with the prior art, the conductive blind via of the power circuit or the ground circuit of the present disclosure is connected only to the electrical contact pads on the end surface of the conductive blind via of the power circuit or the ground circuit, so that the other electrical contact pads connected to the other conductive blind vias do not need to be used as power contacts (or ground contacts). Therefore, the number of available functional contacts (inputs/outputs) can be effectively increased to effectively solve the problem that the number of functional contacts (inputs/outputs) is reduced due to the conventional circuit structure using a single large copper sheet to daisy-chain the power blind via (or ground blind via) with the other conductive blind vias.

Moreover, in the electronic package and the circuit structure thereof of the present disclosure, the plurality of metal sheets spaced apart from each other and not in contact with one another are provided to facilitate stress dispersion. Therefore, compared with the prior art, the circuit structure of the present disclosure can avoid stress concentration, so that the circuit structure is not prone to warping, and cracking can be effectively prevented from occurring to the electronic element.

### BRIEF DESCRIPTION OF THE DRAWINGS

FIG. 1A is a partial top schematic view of a conventional circuit structure.

FIG. 1B is a cross-sectional schematic view of the conventional circuit structure.

FIG. 1C is a side schematic view of the conventional circuit structure.

FIG. 2A is a partial top schematic view of a circuit structure according to the present disclosure.

FIG. 2B is a cross-sectional schematic view of the circuit structure according to the present disclosure.

FIG. 2C is a side schematic view of the circuit structure according to the present disclosure.

FIG. 3 is a cross-sectional schematic view of an electronic package according to the present disclosure.

FIG. 4 is a cross-sectional schematic view of an electronic package according to another embodiment of the present disclosure.

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “a,” “one,” and the like are merely for clear explanation rather than limiting the practicable scope of the present disclosure, and thus, alterations or adjustments of the relative relationships thereof without essentially altering the technical contents should still be considered in the practicable scope of the present disclosure.

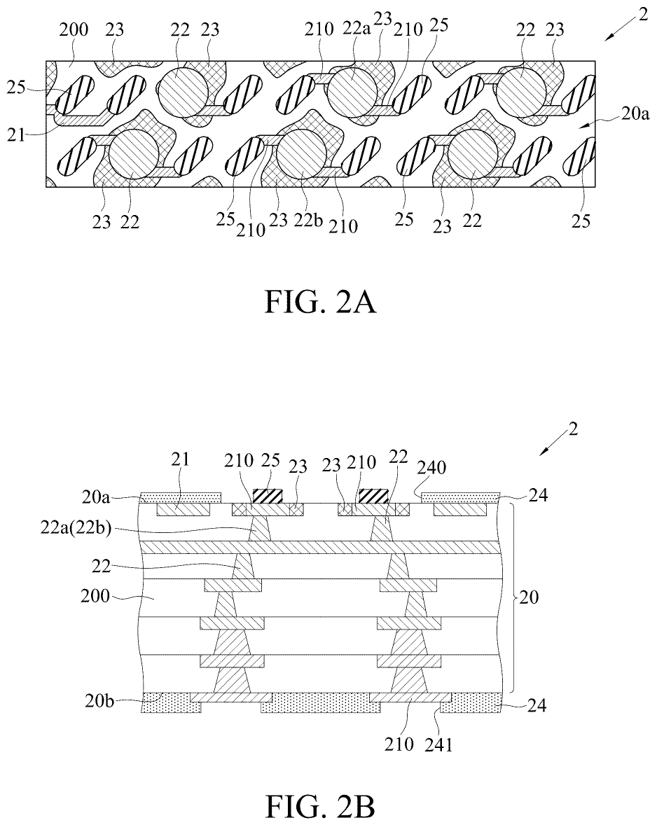

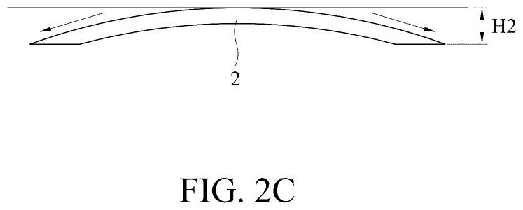

FIG. 2A and FIG. 2B are schematic views of a circuit structure 2 according to the present disclosure.

As shown in FIG. 2A and FIG. 2B, the circuit structure 2 includes an insulating body 20, at least one circuit layer 21 bonded to the insulating body 20, a plurality of conductive blind vias 22 formed in the insulating body 20, and a plurality of metal sheets 23 bonded to the insulating body 20.

In one embodiment, the circuit structure 2 is a coreless circuit stacking structure.

In other embodiments, the circuit structure 2 may be applied to a substrate structure with a core layer or without a core layer, a through-silicon interposer (TSI) with conductive through-silicon vias (TSVs), or other board types, but the present disclosure is not limited to as such.

The insulating body 20 is defined with a first side 20a and a second side 20b opposite to the first side 20a. The insulating body 20 includes at least one insulating layer 200.

In one embodiment, the insulating layer 200 is a dielectric layer and is made of polybenzoxazole (PBO), polyimide (PI), prepreg (PP), or other dielectric materials.

The circuit layer 21 is formed with a plurality of electrical contact pads 210 on the first side 20a and/or the second side 20b of the insulating body 20.

In one embodiment, the circuit layer 21 is formed in accordance with a redistribution layer (RDL) specification. For example, the circuit layer 21 is made of copper.

Moreover, an insulating protective layer 24 made of such as a solder-resist material or graphite can be formed on the first side 20a and/or the second side 20b of the insulating body 20 as required to serve as a solder mask layer, wherein the insulating protective layer 24 covers the circuit layer 21.

For example, in the insulating protective layer 24, an opening 240 exposing the plurality of electrical contact pads 210 may be formed on the first side 20a of the insulating body 20 for bonding to a plurality of conductive bumps 25. Alternatively, in the insulating protective layer 24, a plurality of holes 241 exposing the electrical contact pads 210 may be formed on the second side 20b of the insulating body 20 for externally connecting to conductors.

The conductive blind vias 22 are electrically connected to the circuit layer 21 at the first side 20a and the second side 20b of the insulating body 20, so that each conductive blind via 22 is connected to at least two electrical contact pads 210, as shown in FIG. 2A.

In one embodiment, at least one conductive blind via 22 on the first side 20a of the insulating body 20 is served as a power circuit 22a or a ground circuit 22b and is connected to two electrical contact pads 210.

The metal sheets 23 are disposed on the first side 20a and/or the second side 20b of the insulating body 20 and are adjacent to the conductive blind vias 22, wherein the metal sheets 23 are spaced apart from each other and are not in contact with one another.

In one embodiment, the plurality of metal sheets 23 are formed on the first side 20a of the insulating body 20 and are exposed from the opening 240, wherein each metal sheet 23 is connected to only one conductive blind via 22.

Therefore, in the circuit structure 2 of the present disclosure, the metal sheets 23 are spaced apart from each other and are not in contact with one another, so that a copper-break structure is formed, and each metal sheet 23 is not daisy-chained to multiple conductive blind vias. Therefore, compared with the prior art, the conductive blind via 22 of the power circuit 22a or the ground circuit 22b of the present disclosure is connected only to the electrical contact pads 210 on the end surface of the conductive blind via 22 of the power circuit 22a or the ground circuit 22b, so that the other electrical contact pads 210 connected to the other conductive blind vias 22 do not need to be used as power contacts (or ground contacts). Therefore, the number of available functional contacts (inputs/outputs) can be effectively increased to effectively solve the problem that the number of functional contacts (inputs/outputs) is reduced due to the conventional circuit structure using a single large copper sheet to daisy-chain the power blind via (or ground blind via) with the other conductive blind vias.

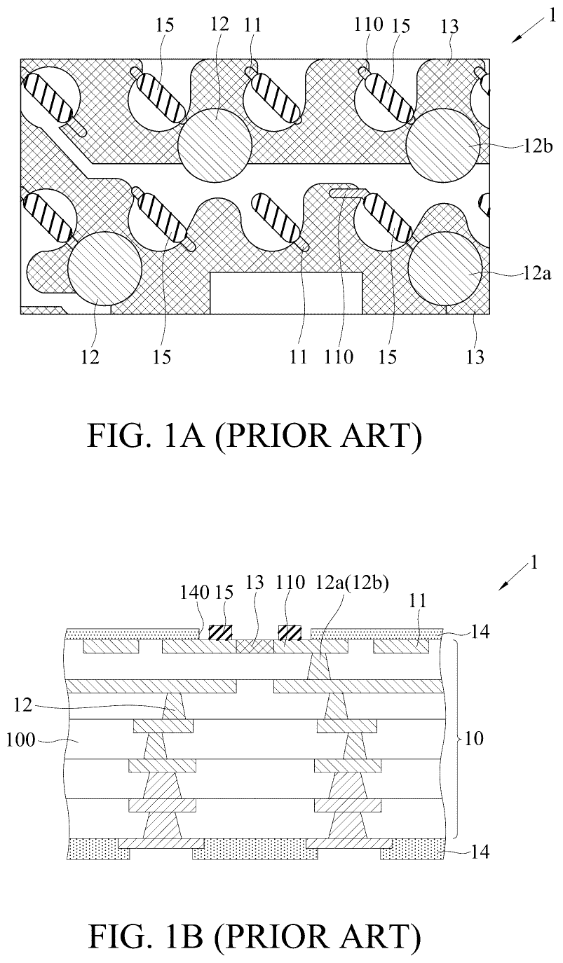

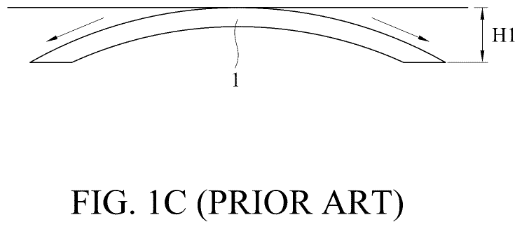

Furthermore, the circuit structure 2 of the present disclosure is provided with the plurality of metal sheets 23 (which are spaced apart from each other and are not in contact with one another) on the first side 20a of the insulating body 20 to facilitate stress dispersion. Therefore, compared with the prior art, the circuit structure 2 of the present disclosure can avoid stress concentration, so that the circuit structure 2 is not prone to warpage. The warpage height difference H2 shown in FIG. 2C is smaller than the warpage height difference H1 of the prior art in FIG. 1.

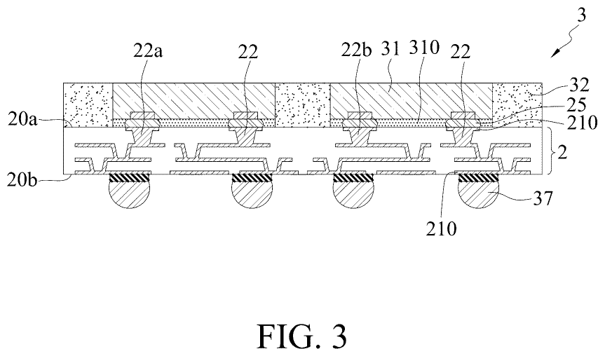

FIG. 3 is a cross-sectional schematic view illustrating an application of the circuit structure 2 according to the present disclosure. As shown in FIG. 3, a plurality of electronic elements 31 are disposed on the circuit structure 2, and a packaging layer 32 for encapsulating the electronic elements 31 is formed on the circuit structure 2, thereby forming an electronic package 3 conforming to a fan-out multi-chip module (FOMCM) specification.

The electronic elements 31 may be active elements, passive elements, package modules, and/or the like. The electronic elements 31 are disposed on the first side 20a of the circuit structure 2. The active elements are such as semiconductor chips, and the passive elements are such as resistors, capacitors, and/or inductors.

In one embodiment, the electronic elements 31 are semiconductor chips and are electrically connected to the electrical contact pads 210 of the first side 20a of the circuit structure 2 via the plurality of conductive bumps 25 in a flip-chip manner. An underfill 310 is formed between the electronic elements 31 and the circuit structure 2 and encapsulates the conductive bumps 25.

The packaging layer 32 may be made of an insulating material such as polyimide (PI), dry film, epoxy, molding compound, or other suitable materials. The packaging layer 32 is bonded to the first side 20a of the circuit structure 2, so that the packaging layer 32 further encapsulates the underfill 310.

In one embodiment, a plurality of conductive elements 37 such as solder balls may be formed on the electrical contact pads 210 of the circuit layer 21 on the second side 20b of the circuit structure 2.

Therefore, the electronic package 3 incorporating the circuit structure 2 has an increased number of functional contacts (inputs/outputs), enabling support for multiple high-pin-count electronic elements 31 to fulfill multifunctional requirements.

In addition, the electronic package 3 leveraging the circuit structure 2 can avoid stress concentration and is thus less prone to warping. Therefore, compared with the prior art, cracking can be effectively prevented from occurring in the electronic elements 31 of the electronic package 3 of the present disclosure.

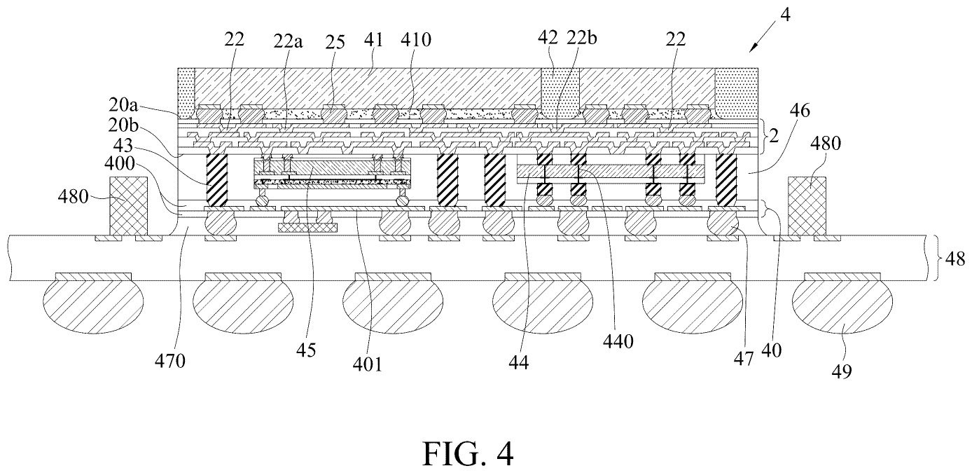

FIG. 4 is a cross-sectional schematic view illustrating another application of the circuit structure 2 according to the present disclosure. As shown in FIG. 4, the circuit structure 2 is implemented in an electronic package 4 conforming to a fan-out embedded bridge (FOEB) specification.

In the electronic package 4, at least one intermediate element 44 having a plurality of conductive through-silicon vias (TSVs) 440, at least one electrical bridge element (bridge die) 45, a plurality of conductive pillars 43, and an encapsulation layer 46 are disposed on a carrying structure 40. The intermediate element 44, the electrical bridge element 45, and the conductive pillars 43 are encapsulated by the encapsulation layer 46, and the second side 20b of the circuit structure 2 is disposed on the encapsulation layer 46, so that the circuit structure 2 is electrically connected to the intermediate element 44, the electrical bridge element 45, and the conductive pillars 43.

Moreover, a plurality of electronic elements 41 are disposed on the first side 20a of the circuit structure 2 via the plurality of conductive bumps 25 in a flip-chip manner. An underfill 410 is formed between the electronic elements 41 and the circuit structure 2 and encapsulates the conductive bumps 25. A packaging layer 42 is formed on the circuit structure 2 and encapsulates the electronic elements 41.

In one embodiment, the carrying structure 40 is a routing structure (e.g., a wiring structure) and has at least one dielectric layer 400 and at least one routing layer 401 (e.g., a wiring layer) bonded to the dielectric layer 400. The routing layer 401 is electrically connected to the intermediate element 44, the electrical bridge element 45, and the conductive pillars 43. For example, the routing layer 401 is made of copper, and the dielectric layer 400 is made of polybenzoxazole (PBO), polyimide (PI), prepreg (PP), or other dielectric materials.

Furthermore, a plurality of conductive elements 47 such as solder balls may be formed on the routing layer 401 on the bottom side of the carrying structure 40 to be connected to a routing carrier 48 (e.g., a wiring carrier). Then, the conductive elements 47 may be encapsulated by an underfill 470. For example, the routing carrier 48 is a board made of an organic material (such as a package substrate with a core layer or a circuit structure without a core layer) or a board made of an inorganic material (such as a silicon board).

In addition, at least one electrical functional element 480 may be disposed on the upper side of the routing carrier 48 as required. The lower side of the routing carrier 48 can be connected to an electronic device (not shown) such as a circuit board via a plurality of solder balls 49, so that the routing carrier 48 is electrically connected to the electronic device.

The electrical bridge element 45 incorporated within the electronic package 4 is served as a power management chip (e.g., a power management integrated circuit or power management IC) or an integrated voltage regulator (IVR).

The electronic elements 41 are electrically bridged to the intermediate element 44 and the electrical bridge element 45 via the circuit structure 2.

Therefore, the electronic package 4 incorporating the circuit structure 2 has an increased number of functional contacts (inputs/outputs), enabling support for multiple high-pin-count electronic elements 41 to fulfill multifunctional requirements.

Moreover, the electronic package 4 leveraging the circuit structure 2 can avoid stress concentration and is thus less prone to warping. Therefore, compared with the prior art, cracking can be effectively prevented from occurring in the electronic elements 41 of the electronic package 4 of the present disclosure.

To sum up, in the electronic package and the circuit structure thereof of the present disclosure, the metal sheets of the circuit structure are spaced apart from each other and are not in contact with one another, so that a copper-break structure is formed, and each metal sheet is not daisy-chained to multiple conductive blind vias. Therefore, the number of available functional contacts can be effectively increased, and the stress can be effectively dispersed. Accordingly, the electronic package of the present disclosure can support high-pin-count electronic elements to meet multifunctional requirements, and warping can be prevented from occurring in the circuit structure.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A circuit structure, comprising:
an insulating body including an insulating layer;
a circuit layer formed on the insulating body and having a plurality of electrical contact pads;
a plurality of conductive blind vias formed in the insulating body and electrically connected to the circuit layer, each of the plurality of conductive blind vias being connected to the plurality of electrical contact pads; and
a plurality of metal sheets disposed on the insulating body and adjacent to the plurality of conductive blind vias, the plurality of metal sheets being spaced apart from each other and not in contact with one another.

2. The circuit structure of claim 1, wherein the circuit layer is formed in accordance with a redistribution layer specification.

3. The circuit structure of claim 1, wherein at least one of the plurality of conductive blind vias is used as a power circuit.

4. The circuit structure of claim 1, wherein at least one of the plurality of conductive blind vias is used as a ground circuit.

5. An electronic package, comprising:
the circuit structure of claim 1; and
an electronic element bonded to the plurality of electrical contact pads via a plurality of conductive bumps and electrically connected to the circuit layer.

6. The electronic package of claim 5, wherein the electronic element is disposed on one side of the circuit structure, and a plurality of conductive elements are disposed on the other side of the circuit structure.

7. An electronic package, comprising:
the circuit structure of claim 2; and
an electronic element bonded to the plurality of electrical contact pads via a plurality of conductive bumps and electrically connected to the circuit layer.

8. The electronic package of claim 7, wherein the electronic element is disposed on one side of the circuit structure, and a plurality of conductive elements are disposed on the other side of the circuit structure.

9. An electronic package, comprising:
the circuit structure of claim 3; and
an electronic element bonded to the plurality of electrical contact pads via a plurality of conductive bumps and electrically connected to the circuit layer.

10. The electronic package of claim 9, wherein the electronic element is disposed on one side of the circuit structure, and a plurality of conductive elements are disposed on the other side of the circuit structure.

11. An electronic package, comprising:
the circuit structure of claim 4; and
an electronic element bonded to the plurality of electrical contact pads via a plurality of conductive bumps and electrically connected to the circuit layer.

12. The electronic package of claim 11, wherein the electronic element is disposed on one side of the circuit structure, and a plurality of conductive elements are disposed on the other side of the circuit structure.

13. An electronic package, comprising:
a carrying structure including a routing layer;
a plurality of conductive pillars disposed on one side of the carrying structure and electrically connected to the routing layer;
an encapsulation layer encapsulating the plurality of conductive pillars;
the circuit structure of claim 1 disposed on the encapsulation layer and electrically connected to the plurality of conductive pillars; and
an electronic element bonded to the plurality of electrical contact pads via a plurality of conductive bumps and electrically connected to the circuit layer.

14. The electronic package of claim 13, wherein the encapsulation layer is embedded with an intermediate element having a plurality of conductive through-silicon vias and electrically connected to the routing layer and the circuit layer.

15. The electronic package of claim 13, wherein the encapsulation layer is embedded with an electrical bridge element electrically connected to the routing layer and the circuit layer.

16. The electronic package of claim 13, further comprising: a plurality of conductive elements disposed on the other side of the carrying structure.

17. An electronic package, comprising:
a carrying structure including a routing layer;
a plurality of conductive pillars disposed on one side of the carrying structure and electrically connected to the routing layer;
an encapsulation layer encapsulating the plurality of conductive pillars;
the circuit structure of claim 2 disposed on the encapsulation layer and electrically connected to the plurality of conductive pillars; and
an electronic element bonded to the plurality of electrical contact pads via a plurality of conductive bumps and electrically connected to the circuit layer.

18. The electronic package of claim 17, wherein the encapsulation layer is embedded with an intermediate element having a plurality of conductive through-silicon vias and electrically connected to the routing layer and the circuit layer.

19. The electronic package of claim 17, wherein the encapsulation layer is embedded with an electrical bridge element electrically connected to the routing layer and the circuit layer.

20. The electronic package of claim 17, further comprising: a plurality of conductive elements disposed on the other side of the carrying structure.

21. An electronic package, comprising:
a carrying structure including a routing layer;
a plurality of conductive pillars disposed on one side of the carrying structure and electrically connected to the routing layer;
an encapsulation layer encapsulating the plurality of conductive pillars;
the circuit structure of claim 3 disposed on the encapsulation layer and electrically connected to the plurality of conductive pillars; and
an electronic element bonded to the plurality of electrical contact pads via a plurality of conductive bumps and electrically connected to the circuit layer.

22. The electronic package of claim 21, wherein the encapsulation layer is embedded with an intermediate element having a plurality of conductive through-silicon vias and electrically connected to the routing layer and the circuit layer.

23. The electronic package of claim 21, wherein the encapsulation layer is embedded with an electrical bridge element electrically connected to the routing layer and the circuit layer.

24. The electronic package of claim 21, further comprising: a plurality of conductive elements disposed on the other side of the carrying structure.

25. An electronic package, comprising:
a carrying structure including a routing layer;
a plurality of conductive pillars disposed on one side of the carrying structure and electrically connected to the routing layer;
an encapsulation layer encapsulating the plurality of conductive pillars;
the circuit structure of claim 4 disposed on the encapsulation layer and electrically connected to the plurality of conductive pillars; and
an electronic element bonded to the plurality of electrical contact pads via a plurality of conductive bumps and electrically connected to the circuit layer.

26. The electronic package of claim 25, wherein the encapsulation layer is embedded with an intermediate element having a plurality of conductive through-silicon vias and electrically connected to the routing layer and the circuit layer.

27. The electronic package of claim 25, wherein the encapsulation layer is embedded with an electrical bridge element electrically connected to the routing layer and the circuit layer.

28. The electronic package of claim 25, further comprising: a plurality of conductive elements disposed on the other side of the carrying structure.
